(19) United States
(12) Patent Application Publication
(10) Pub. No.: US 2026/0103820 A1
(43) Pub. Date: Apr. 16, 2026

(54) METHOD FOR PREPARING FULLERENE SINGLE-CRYSTAL FILMS AND USES FIELD OF TECHNOLOGY

(71) Applicant: ZHEJIANG UNIVERSITY, Hangzhou (CN)

(72) Inventors: Hanying LI, Hangzhou (CN); Yujie ZHAO, Hangzhou (CN); Boyu PENG, Hangzhou (CN)

(73) Assignee: ZHEJIANG UNIVERSITY, Hangzhou (CN)

(21) Appl. No.: 18/873,715

(22) PCT Filed: Jul. 26, 2023
(86) PCT No.: PCT/CN2023/109278

§ 371 Date: Dec. 10, 2024

(30) Foreign Application Priority Data
Jul. 5, 2023 (CN) 202310815204X

(51) Int. Cl. C30B 7/06; C30B 29/02; H10K 10/46; H10K 30/20; H10K 85/20

(52) U.S. Cl. CPC C30B 7/06; C30B 29/02; H10K 85/211; H10K 10/484; H10K 30/20

(57) ABSTRACT

The present disclosure relates to the field of organic semiconductor technology, it relates to a method for preparing fullerene single-crystal films and uses. A method for preparing fullerene single-crystal films using a gas-liquid-solid three-phase interface, including the following steps: 1) mixing fullerene and solvent to form a mixture; 2) employing a solution shear method to induce crystallization growth of the fullerene in mixture on a substrate surface, thereby obtaining the fullerene single-crystal films. The present disclosure prepares large-area fullerene single-crystal films by directly controlling the nucleation density of fullerenes at the three-phase line and utilizing the continuous movement of the three-phase line. The resulting films have the advantages of uniform alignment, high uniformity, and high coverage. Additionally, they exhibit excellent electronic transport properties, meeting the application requirements in the field of optoelectronics.

### FIELD OF TECHNOLOGY

The present disclosure relates to the field of organic semiconductor technology, in particular it relates to a method for preparing fullerene single-crystal films and uses.

### BACKGROUND

As a star material in the field of optoelectronics, fullerene has broad application prospects in various areas of organic electronics, such as organic solar cells, organic field-effect transistors, organic light-emitting diodes, and organic photodetectors. Up to date, these applications of fullerene have been validated at the laboratory stage. However, fullerene has yet to achieve industrial applications in the optoelectronic field. This is primarily due to the fact that the current methods for preparing fullerene films typically involve vacuum deposition. Vacuum deposition requires harsh conditions such as high temperatures (over 400° C.) and high vacuum, as well as expensive equipment (ACS Nano 2013, 7, 10, 9122-9128). These factors lead to high costs and energy consumption for fullerene preparation, which hinders its industrial production and application. Additionally, fullerene films produced by vacuum deposition tend to have a higher density of defect states compared to fullerene crystals, adversely affecting their optoelectronic properties, such as electron mobility and exciton diffusion length.

Therefore, it is essential to develop low-cost solution methods for preparing fullerene crystals. In fact, the crystallization process of fullerene is more challenging to control compared to other planar conjugated organic semiconductors due to its unique zero-dimensional structure. This difficulty manifests in two main ways: first, the contact area between fullerene molecules is much smaller compared to planar molecules, resulting in a weaker driving force for crystallization; second, the zero-dimensional nature of fullerene molecules leads to easy rotation and a lack of preferred alignment. Traditional methods for preparing fullerene crystals include liquid-liquid interfacial precipitation (Small 2018, 14, 11, e1703624) and supramolecular gel crystallization (Adv. Sci. 2022, 9, 2203662). Among these, the most common method is liquid-liquid interfacial precipitation, which utilizes the slow mixing of a good solvent and a poor solvent at the interface to induce supersaturation and promote crystal nucleation and growth. Despite receiving considerable attention and research, this method has significant drawbacks, such as the uncontrollable nature of the nucleation and growth processes, leading to poor experimental reproducibility and a chaotic size distribution of fullerene crystals. Moreover, since this method is a non-in-situ growth process, it requires complex transfer procedures to utilize the crystals for optoelectronic applications, which inevitably damages the crystals and complicates the miniaturization and integration of devices.

Accordingly, to enable the practical application of fullerene, it is crucial to adopt solution-based in-situ preparation methods for fullerene single-crystal films. In recent years, scientists have attempted to tackle this challenge. For instance, Li et al. (J. Am. Chem. Soc. 2012, 134, 2760-2765) used a droplet-pinned crystallization method to obtain single-crystal fullerene up to several hundred micrometers long. However, this method requires a fixed object placed at the center of the substrate to prevent droplet sliding, making it difficult to continuously prepare fullerene single-crystal films with high coverage. Similar issues are present in methods like PDMS-assisted growth (Adv. Mater. 2015, 27, 4371-4376). Moreover, fullerene crystals prepared by these two methods showed chaotic alignment, with different crystal on the same substrate even exhibiting perpendicular alignment. This severely limits the potential for integrating the obtained fullerene single-crystal films into devices. Zheng et al. (Carbon 2018, 126, 299-304) employed a dip-coating method to achieve millimeter-scale fullerene crystal films. However, this method produced fullerene crystals with poor morphology (such as a jagged appearance and uneven thickness) and sub-micrometer thickness, which is detrimental to charge carrier injection and the construction of vertical devices. Additionally, this method requires pulling the substrate out of the bulk solution, leading to significant material waste. Jie et al. (Adv. Funct. Mater. 2021, 31, 2105459) used a solution-phase epitaxy method to fabricate inch-scale fullerene single-crystal nanowire arrays. However, this approach requires a photoresist array as an auxiliary growth layer, resulting in a coverage rate of only about 9% for the fullerene single-crystal array on the substrate, and the process of removing the photoresist can damage the fullerene crystals. In summary, the existing methods for preparing fullerene single-crystal films face significant challenges, including discontinuous growth, chaotic alignment, low coverage, and poor uniformity. Furthermore, the uniformity of the obtained fullerene crystal is often inadequate, as evidenced by large differences in crystal thickness and width. For instance, the performance of transistors fabricated from fullerene crystal exhibits a high variability coefficient, with the mobility variability coefficient reaching 42.9% as reported by Jie et al. in 2021 (Adv. Funct. Mater. 2021, 31, 2105459), which is unfavorable for practical applications.

Another challenge in solution-based methods for preparing fullerene single-crystal films lies in controlling the crystal morphology. Due to the spherical or ellipsoidal shape of fullerene molecules, there can be significant space between the molecules within the crystal, allowing solvents to easily infiltrate and form solvated crystal. This means that the choice of solvent directly impacts the composition and morphology of the fullerene crystal. For example, Park et al. (Chem. Commun. 2009, 32, 4803-4805) demonstrated that the geometric configuration of the solvent affects the morphology of fullerene crystal. Hexagonal crystal can be obtained in pseudo-three-dimensional solvents like carbon tetrachloride, while one-dimensional needle-like crystal form in meta-substituted pseudo-two-dimensional aromatic solvents. Therefore, the selection and control of solvents are crucial for preparing fullerene single-crystal films via solution methods. To achieve high coverage and good alignment of fullerene single-crystal films, it is beneficial to manipulate the crystal morphology into a ribbon-like structure by solvent engineering.

In conclusion, to achieve the practical applications of fullerene in the industry, the ideal fullerene films should be high-coverage, uniformly aligned, high-uniformity single-crystal films prepared in situ through solution methods, capable of continuous production. However, current technologies cannot produce such ideal fullerene single-crystal films. The main challenges in this field are: 1) the complex growth process of fullerene crystal, lacking overall control over nucleation and growth; 2) existing in-situ preparation methods often require external environments such as PDMS or photoresist arrays for crystallization growth, resulting in defects like discontinuous growth, chaotic alignment, low coverage, and poor uniformity; 3) the morphology of fullerene crystal heavily depends on the solvent, and how to utilize solvent engineering to achieve fullerene single-crystal films with both good alignment and high coverage remains a puzzle. Thus, the in-situ preparation of ideal large-area fullerene single-crystal films through solution methods remains a significant technical challenge and is a prerequisite for achieving the integration and industrialization of fullerene optoelectronic devices.

### SUMMARY

In view of the above-described disadvantages of the related technology, the present disclosure provides a method for preparing fullerene single-crystal films and uses.

A first aspect according to the present disclosure provides a method for preparing fullerene single-crystal films using a gas-liquid-solid three-phase interface, including the following steps:
1) Mixing fullerene and solvent to form a mixture; and
2) Employing a solution shear method to induce crystallization growth of the fullerene in mixture on a substrate surface, thereby obtaining the fullerene single-crystal films.

In 1), the fullerene is one or more of C60, C70, C76, C78, C80, and C84.

Preferably, the fullerene is one or more of C60, and C70.

In 1), the solvent is one or more of ortho-xylene, 2-methylthiophene, 2-chlorothiophene, 2-chloro-furan, 3-methylthiophene, 2-ethylthiophene, meta-xylene, meta-difluorobenzene, chlorobenzene, ortho-dichlorobenzene, 1,2,4-trichlorobenzene, tetrahydronaphthalene, 1-methylnaphthalene, carbon disulfide, 1,1,2,2-tetrachloroethane, carbon tetrachloride, 2-methoxythiophene, phenethyl ether, 2-chloro-3-methylthiophene, and 2,5-dichlorothiophene.

In 1), a concentration of the fullerene, based on a total volume of the mixture is 0.2 to 20 mg/mL.

Preferably, the concentration is 0.4 mg/ml to 10 mg/mL.

In 2), a material of the substrate is one or more of silicon, indium tin oxide, glass, quartz, sapphire, polyimide, and polyethylene terephthalate.

Preferably, a wetting layer is provided on the substrate.

More preferably, a material of the wetting layer is one or more of benzocyclobutene, polyvinyl alcohol, cross-linked polymethyl methacrylate, cross-linked polystyrene, aluminum oxide, titanium oxide, zinc oxide, ethoxylated polyethyleneimine, phenyltrichlorosilane, gold, and aluminum.

In 2), the solution shear method includes using a shear tool positioned above the substrate, such that the mixture is located between the shear tool and the substrate, and either the substrate or the shear tool is operated at a certain linear velocity.

Preferably, the shear tool is one or more of stainless-steel bar, stainless steel wire bar, polytetrafluoroethylene bar, scrapers, and coating heads.

Preferably, a distance between the shear tool and the substrate is 20 μm to 400 μm.

More preferably, the distance between the shear tool and the substrate is 50 μm to 200 μm.

Preferably, a certain linear velocity in the solution shear method is 1 μm/s to 1 mm/s.

More preferably, the certain linear velocity in the solution shear method is 5 μm/s to 200 μm/s.

In 2), a temperature for the crystallization growth is 20° C. to 120° C.

Preferably, the temperature for the crystallization growth is 25° C. to 60° C.

A second aspect according to the present disclosure provides fullerene single-crystal films prepared by the above-mentioned method.

A third aspect according to the present disclosure provides a use of the above-mentioned fullerene single-crystal films in an optoelectronic device.

A fourth aspect according to the present disclosure provides an optoelectronic device, wherein the optoelectronic device includes the fullerene single-crystal films.

Preferably, the optoelectronic device is one or more of organic field-effect transistors, organic solar cells, organic complementary inverters, organic circuits, organic light-emitting diodes, organic memory devices, organic photodetectors, and organic thermoelectric devices.

As described above, the present disclosure has the following advantages:

The present disclosure directly regulates the nucleation density of fullerene at the three-phase line and utilizes the continuous movement of the three-phase line to prepare large-area fullerene single-crystal films. Additionally, by adjusting the solvent, the morphology of the fullerene crystals can be controlled to obtain large-area fullerene single-crystal films with uniform alignment, high uniformity, and high coverage, achieving the highest coverage rate currently available (greater than 95%).

Using the high-quality fullerene single-crystal films produced by the present disclosure allows for practical applications of fullerene in various fields of organic electronics. Among them, organic field-effect transistors (OFETs) based on C60 fullerene single-crystal films exhibit a coefficient of variation for mobility and threshold voltage of less than 15%, representing the most uniform performance values for OFETs made from single-crystal C60 fullerene to date. OFETs based on C70 fullerene single-crystal films achieve a mobility of 0.195 cm²/V·s, which is the highest mobility reported for OFETs made from single-crystal C70 fullerene. Other applications, such as organic solar cells and organic complementary inverters, also demonstrate excellent performance.

### BRIEF DESCRIPTION OF THE DRAWINGS

FIG. 1 shows overall and magnified optical microscope diagrams of C60 fullerene single-crystal films according to Embodiment 1 in the present disclosure.

FIG. 2 shows an optical microscope diagram of C60 fullerene single-crystal films according to Embodiment 2 in the present disclosure.

FIG. 3 shows an optical microscope diagram of C60 fullerene single-crystal films according to Embodiment 3 in the present disclosure.

FIG. 4 shows an optical microscope diagram of C60 fullerene single-crystal films according to Embodiment 4 in the present disclosure.

FIG. 5 shows an optical microscope diagram of C60 fullerene single-crystal films according to Embodiment 5 in the present disclosure.

FIG. 6 shows an optical microscope diagram of C60 fullerene single-crystal films according to Embodiment 6 in the present disclosure.

FIG. 7 shows an optical microscope diagram of C60 fullerene single-crystal films according to Embodiment 7 in the present disclosure.

FIG. 8 shows overall and magnified optical microscope diagrams of C70 fullerene single-crystal films according to Embodiment 8 in the present disclosure.

FIG. 9 shows an optical microscope diagram of C70 fullerene single-crystal films according to Embodiment 9 in the present disclosure.

FIG. 10 shows characterization of field-effect transistor array fabricated using the C60 fullerene single-crystal films according to Embodiment 10 in the present disclosure. In this context, (a) and (b) represent the transfer characteristic curves and typical output characteristic curves of 70 devices, with the inset in (a) showing a schematic diagrams of organic field-effect transistor structure; (c) and (d) present statistical graphs of mobility and threshold voltage for the 70 devices.

FIG. 11 shows typical transfer and output characteristic curves of field-effect transistors fabricated using C70 fullerene single-crystal films according to Embodiment 11 in the present disclosure.

FIG. 12 shows a schematic structure and a J-V curve of the organic solar cell made from C60 fullerene single-crystal films according to Embodiment 12 in the present disclosure, where, (a) is the schematic structure, and (b) is the J-V curve.

FIG. 13 shows an optical microscope image and performance curves of the organic complementary inverter made from C60 fullerene single-crystal films according to Embodiment 13 in the present disclosure, where, (a) is the optical microscope image, (b) is a voltage conversion curve, with the inset being the circuit schematic of the organic complementary inverter, and (c) is a voltage gain curve.

FIG. 14 shows an optical microscope image of films prepared in Comparative Example 1 according to the present disclosure.

FIG. 15 shows an optical microscope image of films prepared in Comparative Example 2 according to the present disclosure.

FIG. 16 shows an optical microscope image of films prepared in Comparative Example 3 according to the present disclosure.

FIG. 17 shows an optical microscope image of films prepared in Comparative Example 4 according to the present disclosure.

### DETAILED DESCRIPTION

The inventor discovered that the fullerene films prepared by existing technologies have disadvantages such as low crystallinity, small area, disordered alignment, low coverage, and poor uniformity. Through extensive research, it was found that using the solution shear method allows fullerene to crystallize and grow on the substrate surface. By controlling the solvent engineering and the nucleation and growth behavior at the air-solution-solid three-phase line, high-quality large-area fullerene single-crystal films were successfully prepared, said fullerene single-crystal films have high coverage, uniform alignment, high crystallinity, and good uniformity. The fullerene single-crystal films of the present disclosure meet the application requirements of fullerene materials in the optoelectronic field and can be applied in areas such as organic field-effect transistors, organic solar cells, and organic circuits. The present disclosure adopts the following technical scheme:

A first aspect according to the present disclosure provides a method for preparing fullerene single-crystal films using a gas-liquid-solid three-phase interface, comprising the following steps:
1) Mixing fullerene and solvent to form a mixture.
2) Employing a solution shear method to induce crystallization growth of the fullerene in mixture on a substrate surface, thereby obtaining the fullerene single-crystal films.

The method described in the present disclosure does not require additional fixtures or photoresist arrays to assist in crystallization. By controlling the solvent evaporation at the air-solution-substrate three-phase line to promote crystal nucleation and utilizing the continuous movement of the three-phase line to facilitate the continuous growth of fullerene crystals, it is possible to obtain large-area fullerene single-crystal films with high coverage and scalability.

In the method described in the present disclosure 1), the fullerene is one or more of C60, C70, C76, C78, C80, and C84; preferably, the fullerene is one or more of C60, and C70.

In the method described in the present disclosure 1), the solvent is one or more of ortho-xylene, 2-methylthiophene, 2-chlorothiophene, 2-chloro-furan, 3-methylthiophene, 2-ethylthiophene, meta-xylene, meta-difluorobenzene, chlorobenzene, ortho-dichlorobenzene, 1,2,4-trichlorobenzene, tetrahydronaphthalene, 1-methylnaphthalene, carbon disulfide, 1,1,2,2-tetrachloroethane, carbon tetrachloride, 2-methoxythiophene, phenethyl ether, 2-chloro-3-methylthiophene, and 2,5-dichlorothiophene; the solvent can be a single type of solvent, such as 2-chlorothiophene, 2-chloro-3-methylthiophene, 2-methoxythiophene, 3-methylthiophene, 2-ethylthiophene, or o-xylene. Fullerene crystal tend to couple solvent molecules within the crystal structure, forming solvated crystals; therefore, fullerene crystals often exhibit different morphologies in different solvents. For example, C60 fullerene typically forms needle-like crystals in meta-xylene, while it tends to form hexagonal crystals in carbon tetrachloride. To achieve the highest possible coverage of fullerene single-crystal films on the substrate, the present disclosure selects solvents that can yield ribbon-like crystal with good alignment and high coverage. When the crystals exhibit other morphologies in a single solvent, a second solvent can be introduced to modulate the crystal morphology. For example, C60 fullerene crystals in carbon tetrachloride display disordered, discontinuous, and low-coverage hexagonal crystals. In this case, solvents such as meta-xylene, 3-methylthiophene, or toluene, which can help form needle-like crystals, may be added. This combination allows for the merging of both morphological features to create ribbon-like crystals with good alignment and high coverage. The use of two solvents can increase the coverage of fullerene single-crystal films by at least eight times. For example, the solvent can be a mixture of two or more solvents, such as a combination of 3-methylthiophene and carbon tetrachloride, 2-chlorothiophene and meta-xylene, or 2-chlorothiophene and 2-methylthiophene. Furthermore, when the solvent is a mixture of 3-methylthiophene and carbon tetrachloride, the volume ratio of 3-methylthiophene to carbon tetrachloride can be 1: (1-5), and it may also be 1: (1-2.5), 1: (2-4.2), or 1: (3.6-5), specifically 1:3. When the solvent is a mixture of 2-chlorothiophene and meta-xylene, the volume ratio of 2-chlorothiophene to meta-xylene can be (1-6): 1, and it can also be (1-3): 1, (1.5-4.6): 1, (3.6-5.8): 1, or (4.2-6): 1, specifically 4:1. When the solvent is a mixture of 2-chlorothiophene and meta-xylene, the volume ratio of 2-chlorothiophene to meta-xylene can be (1-15): 1, and it may also be (1-4.2): 1, (3.4-5.6): 1, (4.8-10.3): 1, or (8.6-15): 1, specifically 9:1.

In the method described in the present disclosure, the concentration of fullerene, based on the total volume of the mixed solution, ranges from 0.2 to 20 mg/mL. For example, it can be within any of the ranges of 0.4 mg/ml to 2.2 mg/mL, 2.8 mg/mL to 3.2 mg/mL, 2.9 mg/mL to 4.6 mg/ml, 3.6 mg/mL to 6.1 mg/mL, 5.7 mg/mL to 7.2 mg/mL, 6.9 mg/mL to 9.2 mg/mL, 8.3 mg/mL to 10 mg/mL, or 0.4 mg/mL to 10 mg/mL. In some embodiments it can be 0.45 mg/ml, 3 mg/mL, 6 mg/mL, 7.5 mg/mL, 9 mg/mL, 10 mg/mL.

In the method described in the present disclosure 2), a material of the substrate is one or more of silicon, indium tin oxide, glass, quartz, sapphire, polyimide, and polyethylene terephthalate; preferably, the substrate is silicon or indium tin oxide (ITO), such as a silicon wafer heavily doped with phosphorus or boron. In one embodiment, the wafer is a silicon wafer heavily doped with phosphorus and coated with a layer of silicon dioxide with a thickness of 285 nm.

In the method described in the present disclosure, in 2), a wetting layer is provided on the substrate. Preferably, a material of the wetting layer is one or more of benzocyclobutene (BCB), polyvinyl alcohol (PVA), cross-linked polymethyl methacrylate (c-PMMA), cross-linked polystyrene (c-PS), aluminum oxide (Al₂O₃), titanium oxide (TiO₂), zinc oxide (ZnO), ethoxylated polyethyleneimine (PEIE), phenyltrichlorosilane (PTS), gold (Au), and aluminum (Al). The preparation method of the wetting layer can be spin coating (for polymers), vapor deposition (for metals), sol-gel method (for metal oxides), or vapor-phase method (for self-assembled monolayers). For instance, when the material is a polymer such as PVA, c-PMMA, or c-PS, spin coating is used; when the material is a metal such as Au or Al, vapor deposition is applied; when the material is a metal oxide such as Al₂O₃, TiO₂, or ZnO, the sol-gel method is used; and when the material is a self-assembled monolayer such as PTS, the vapor-phase method is used. In some specific embodiments, the material of the wetting layer is BCB, c-PMMA, Au, PEIE, or PTS.

In the method described in the present disclosure 2), the solution shear method includes using a shear tool positioned above the substrate, such that the mixture is located between the shear tool and the substrate, and either the substrate or the shear tool is operated at a certain linear velocity. Preferably, the shear tool is one or more of stainless-steel bar, stainless steel wire bar, polytetrafluoroethylene bar, scrapers, and coating heads; In one specific embodiment, a stainless-steel bar is used. Preferably, the distance between the shearing tool and the substrate is 20 μm to 400 μm, for example, 50 μm to 150 μm, 100 μm to 250 μm, 200 μm to 350 μm, 300 μm to 400 μm, 50 μm to 200 μm, or 100 μm. Preferably, the linear velocity in the solution shearing method is 1 μm/s to 1 mm/s, for example, 5 μm/s to 105 μm/s, 58 μm/s to 155 μm/s, 126 μm/s to 205 μm/s, 189 μm/s to 450 μm/s, 350 μm/s to 600 μm/s, 550 μm/s to 780 μm/s, 700 μm/s to 950 μm/s, 820 μm/s to 1 mm/s, or specifically 8 μm/s, 10 μm/s, 12 μm/s, 15 μm/s, or 20 μm/s.

In the method described in the present disclosure 2), the crystallization growth temperature ranges from 20° C. to 120° C., for example, from 20° C. to 45° C., 36° C. to 58° C., 47° C. to 78° C., 62° C. to 96° C., 84° C. to 105° C., 96° C. to 120° C., or 25° C. to 60° C. In some specific embodiments, the temperature may be 25° C., 30° C., 35° C., 40° C., 45° C., 50° C., or 60° C. Due to the challenges associated with the growth of fullerene crystal, it is necessary to finely regulate growth conditions such as substrate temperature, shearing speed, and solution concentration to control the nucleation and growth processes of the crystal. For instance, if the temperature is too high, the solvent evaporates too quickly, resulting in excessively high nucleation density at the gas-liquid-solid three-phase boundary, and sufficient solute is available for growth in all directions, leading to disordered alignment and poor morphology of the fullerene crystal, such as increased roughness. In this case, the shearing speed may be increased, and the concentration of the solution reduced. Conversely, if the temperature is too low, slow solvent evaporation hinders nucleation at the three-phase boundary, resulting in the formation of disordered amorphous structures. To address this, the shearing speed may be reduced, and the solution concentration increased.

The second aspect of the present disclosure provides the fullerene single-crystal films obtained by the above-mentioned preparation method. The fullerene single-crystal films produced by this method can achieve a coverage of over 90%. The coverage rate is determined by observing the fullerene single-crystal films under an optical microscope and analyzing the images using ImageJ software.

The third aspect of the present disclosure provides the use of the fullerene single-crystal films in the preparation of optoelectronic devices.

The fourth aspect of this present disclosure provides an optoelectronic device that includes the above-mentioned fullerene single-crystal films.

The optoelectronic device described in the present disclosure can be one or more of organic field-effect transistor, organic solar cell, organic complementary inverter, organic circuit, organic light-emitting diode, organic memory device, organic photodetector, or organic thermoelectric device.

If the optoelectronic device is organic field-effect transistor, its preparation method is as follows:
1) fabricate source and drain electrodes on the above-mentioned fullerene single-crystal films to obtain the organic field-effect transistor.

Source and drain electrodes are collectively referred to as source(S) and drain (D). Voltage and current between the source and the drain are denoted as VDS and IDS, respectively, when a voltage is applied to the gate (G) electrode, the electric field influences the current between the source and drain through the gate dielectric layer.

Preferably, the method for fabricating the source and drain electrodes is one or more of vapor deposition, transfer printing, and printing.

Preferably, the source and drain electrodes are made of one or more of silver, lithium fluoride/aluminum, gold, graphene, calcium, and magnesium.

If the optoelectronic device is organic solar cell, the preparation method is as follows:
1) Fabricate a donor material layer on the fullerene single-crystal films to form a bilayer structure film.
2) Fabricate a top electrode on the bilayer structure film to obtain the organic solar cell.

Preferably, the donor material layer is made from donor small molecules or donor polymers. More preferably, the donor small molecules are selected from 2-((7-(4-(dimethylamino)phenyl)benzo[c][1,2,5]thiadiazol-4-yl)methylene) malononitrile (DTDCPB), and the donor polymer is selected from poly(3-hexylthiophene-2,5-diyl) (P3HT).

Preferably, the donor material layer in 1) is fabricated using one or both of spin coating and vapor deposition methods.

Preferably, the top electrode in 2) is selected from gold, molybdenum trioxide/silver, platinum, titanium, or chromium.

Preferably, the fabrication method for the top electrode in 2) is one or more of vapor deposition, transfer printing, and printing.

If the optoelectronic device is organic complementary inverter, the preparation method is as follows:
1) Grow p-type semiconductor thin films on another side of the substrate containing the above-mentioned fullerene single-crystal films.
2) Vapor deposit electrodes on the substrate containing both the fullerene single-crystal films and the p-type semiconductor thin film to obtain the organic complementary inverter.

Preferably, the growth method for the p-type semiconductor thin film in 1) is one or more of solution shearing, droplet-pinned crystallization, vapor deposition, and physical vapor transport methods.

Preferably, the p-type semiconductor thin film in 1) is made of one or more of fused heterocycles and benzofused heterocyclic derivatives, acene compounds and their derivatives, oligothiophene derivatives, and porphyrin derivatives.

Preferably, the electrodes in 2) are one or both of silver and gold.

The fullerene single-crystal films obtained by the method of the present disclosure has a coverage ratio exceeding 95%, offering advantages such as large area, high uniformity, and uniform alignment.

The organic field-effect transistor array fabricated with the C60 fullerene single-crystal films from the present disclosure exhibits excellent electron transport properties, with the highest electron mobility in the transistor array exceeding 1 cm²V⁻¹s⁻¹, and a coefficient of variation for electron mobility of only 13.3%, significantly lower than the 42.9% reported in existing literature. The organic field-effect transistor array made from C70 fullerene single-crystal film achieves an electron mobility of 0.195 cm²V⁻¹s⁻¹, much higher than the 0.0132 cm²V⁻¹s⁻¹ reported in the literature. The organic solar cell produced using the C60 fullerene single-crystal films from the present disclosure demonstrates a favorable photovoltaic effect, with a photoelectric conversion efficiency reaching 0.123%. The organic complementary inverter fabricated using the fullerene single-crystal film of this invention exhibits almost no voltage loss and has a high voltage gain. In summary, the fullerene single-crystal films obtained by the method of this invention shows practical application potential in the fields of optoelectronics and complementary circuit integration.

The embodiments of the present disclosure will be described below. Those skilled can easily understand disclosure advantages and effects of the present disclosure according to contents disclosed by the specification.

The present disclosure can also be implemented or applied through other different exemplary embodiments. Various modifications or changes can also be made to all details in the specification based on different points of view and applications without departing from the spirit of the present disclosure.

Before further describing specific embodiments of the present disclosure, it should be understood that the scope of protection of the present disclosure is not limited to the specific embodiments described below; it should also be understood that the terms used in the embodiments of the present disclosure are intended to describe specific benzo fused embodiments and are not intended to limit the scope of protection of the present disclosure. Throughout this specification and claims, unless otherwise explicitly indicated in the text, singular terms such as “a,” “one,” and “this” also include their plural forms.

When a range of values is given in the embodiments, it is to be understood that both endpoints of each range of values, and any of the values between the two endpoints, may be chosen unless otherwise stated in the present disclosure. Unless otherwise defined, all technical and scientific terms used in the present disclosure have the same meaning as commonly understood by those skilled in the art. In addition to the specific methods, apparatus, and materials used in the embodiments, any method, apparatus, and material of the prior art similar to or equivalent to the methods, apparatus, and materials described in the embodiments of the present disclosure may be used to implement the present disclosure according to the mastery of the prior art and the documentation of the present disclosure by a person skilled in the art.

### Embodiments 1-9

In embodiments 1-9, large-area fullerene single-crystal films were prepared according to the materials and parameters in Table 1. The preparation method includes the following steps:
1) Using silicon wafers, quartz wafers, or ITO as the substrate, a wetting layer is modified onto the substrate, which is then placed on a heating stage for heating. When the wetting layer material is a polymer such as BCB, c-PMMA, or PEIE, spin coating is used; When the wetting layer material is Au, vapor deposition is used; when the wetting layer material is PTS, a vapor phase method is used. The silicon wafer used is a p-type heavily doped silicon wafer with a 285 nm thick layer of silicon dioxide on the surface.
2) Fullerene and solvent are mixed to form a mixture, said mixture is then homogenized through ultrasonication. The bar is positioned approximately 100 μm above the substrate surface. The mixture is injected into the gap between a stainless-steel bar and the substrate. After the mixture stabilizes, the heating stage moves at a constant linear speed. At the end of the process, large-area fullerene single-crystal films are formed on the substrate.

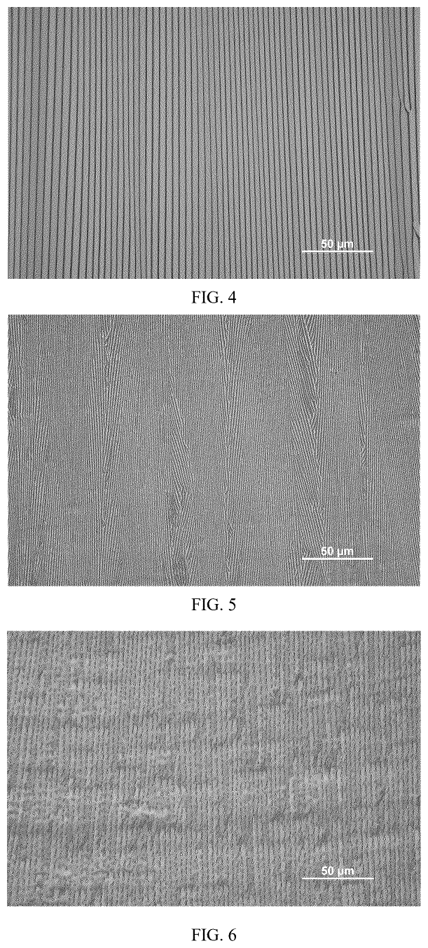

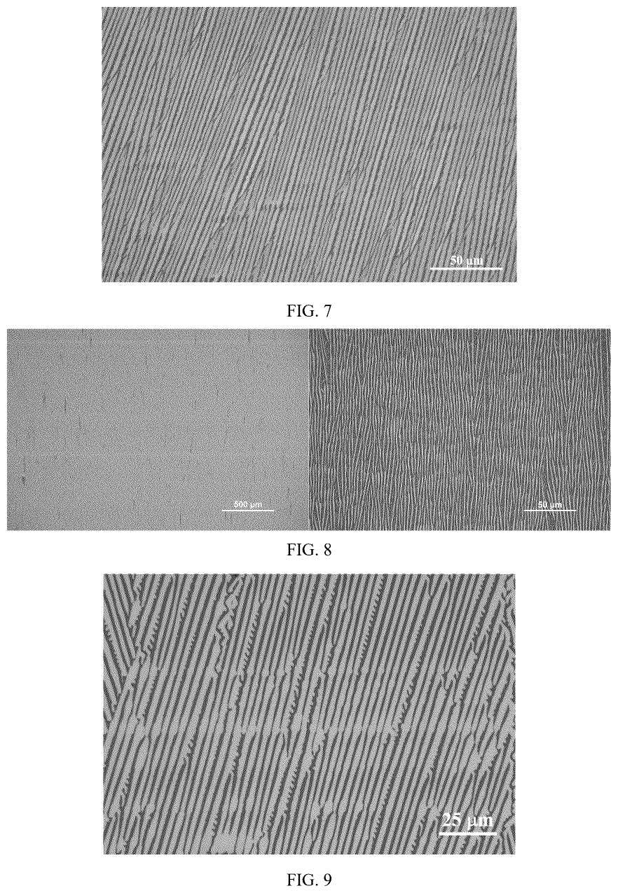

The morphology of the fullerene single-crystal films obtained in embodiments 1-9 was characterized by optical microscopy, with results shown in FIGS. 1-9.

As seen in (a) in FIG. 1, the method described in the present disclosure can produce large-area fullerene single-crystal films; (b) in FIG. 1 shows that in the C60 fullerene single-crystal film obtained in embodiment 1, each crystal has the same alignment and similar color, with no significant morphological defects such as cracks, voids, or dendritic structures, indicating that the method of the present disclosure can yield highly uniform, aligned, high-quality fullerene single-crystal film. Furthermore, coverage analysis of the fullerene single-crystal films using ImageJ software shows, as seen in FIG. 1b, that the crystal coverage rate reaches 84%.

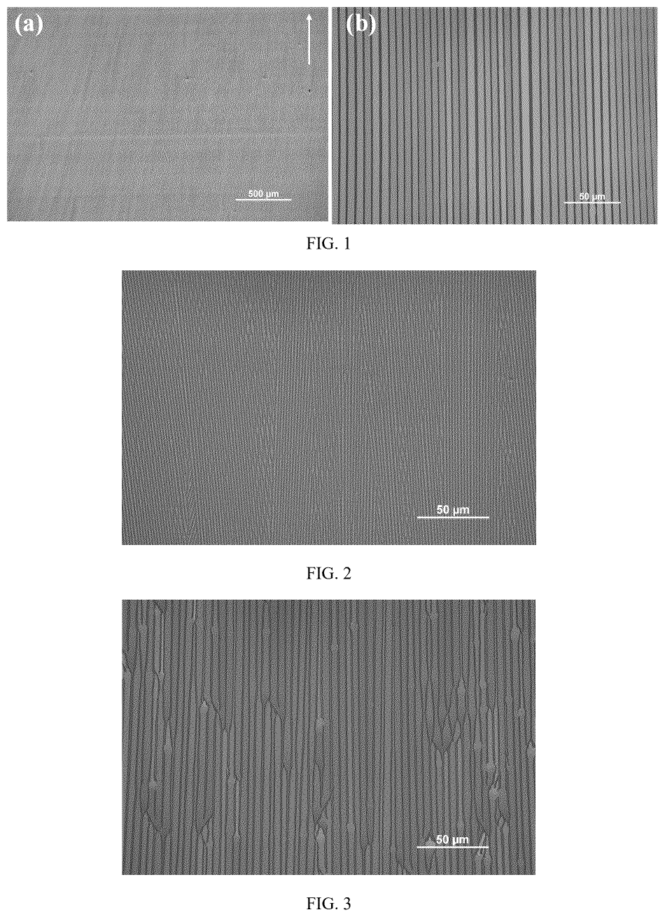

FIGS. 2-9 indicate that the C60 and C70 fullerene single-crystal films obtained by this method have similar alignment and color for each crystal, with a maximum coverage rate exceeding 95%, resulting in uniform alignment, high uniformity, and high coverage fullerene single-crystal films. The specific coverage values of fullerene single-crystal films in embodiments 1-9 are shown in Table 1.

TABLE 1

| | | | | | Concentration | Growth | | |
|---|---|---|---|---|---|---|---|---|
| | Fullerene | | | Wetting | of Mixture | Temperature | Speed | |
| Embodiment | Material | Solvent | Substrate | Agent | (mg/mL) | (° C.) | (μm/s) | Coverage |
| Embodiment | C60 | 2- | Silicon | BCB | 7.5 | 35 | 15 | 84% |
| 1 | | chlorothiophene | Wafer | | | | | |
| Embodiment | C60 | 3- | Silicon | BCB | 0.45 | 25 | 10 | 45% |
| 2 | | methylthiophene:carbon | Wafer | | | | | |
| | | tetrachloride = 1:3 | | | | | | |
| Embodiment | C60 | 2- | Silicon | BCB | 3.5 | 35 | 10 | 74% |
| 3 | | chlorothiophene:meta- | Wafer | | | | | |
| | | xylene = 4:1 | | | | | | |
| Embodiment | C60 | 2- | Silicon | BCB | 7.5 | 35 | 15 | 90% |
| 4 | | chlorothiophene:2- | Wafer | | | | | |
| | | methylthiophene = 9:1 | | | | | | |
| Embodiment | C60 | 2-chloro-3- | Silicon | c- | 10 | 45 | 8 | 62% |
| 5 | | methylthiophene | Wafer | PMMA | | | | |
| Embodiment | C60 | 2- | Quartz | Au | 9 | 30 | 10 | 96% |
| 6 | | chlorothiophene | Wafer | | | | | |
| Embodiment | C60 | 2- | ITO | PEIE | 3 | 60 | 12 | 68% |
| 7 | | methoxythiophene | | | | | | |
| Embodiment | C70 | ortho- | Silicon | BCB | 6 | 40 | 10 | 43% |
| 8 | | dimethylbenzene | Wafer | | | | | |
| Embodiment | C70 | 2- | Silicon | PTS | 5 | 50 | 20 | 65% |
| 9 | | ethylthiophene | Wafer | | | | | |
| Comparative | C60 | 2- | Silicon | BCB | 7.5 | 25 | 15 | / |
| Example 1 | | chlorothiophene | Wafer | | | | | |
| Comparative | C60 | 2- | Silicon | BCB | 7.5 | 45 | 15 | / |
| Example 2 | | chlorothiophene | Wafer | | | | | |
| Comparative | C60 | Carbon | Silicon | BCB | 0.45 | 25 | 10 | 5.6% |
| Example 3 | | tetrachloride | Wafer | | | | | |
| Comparative | C60 | Meta- | Silicon | BCB | 3.5 | 35 | 10 | 14% |
| Example 4 | | dimethylbenzene | Wafer | | | | | |

### Embodiment 10

In embodiment 10, an organic field-effect transistor (OFET) array was fabricated using the C60 fullerene single-crystal films obtained in embodiment 1, with the following steps:

The source-drain electrodes were deposited on the C60 fullerene single-crystal films prepared in embodiment 1. Specifically, a mask was fixed on the C60 fullerene single-crystal films, and 1 nm LiF and 80 nm Al were sequentially deposited as source-drain electrodes, while the highly doped silicon substrate and SiO₂/BCB served as the gate electrode and gate insulator, respectively, resulting in an OFET array.

A total of 70 OFETs were produced in this embodiment.

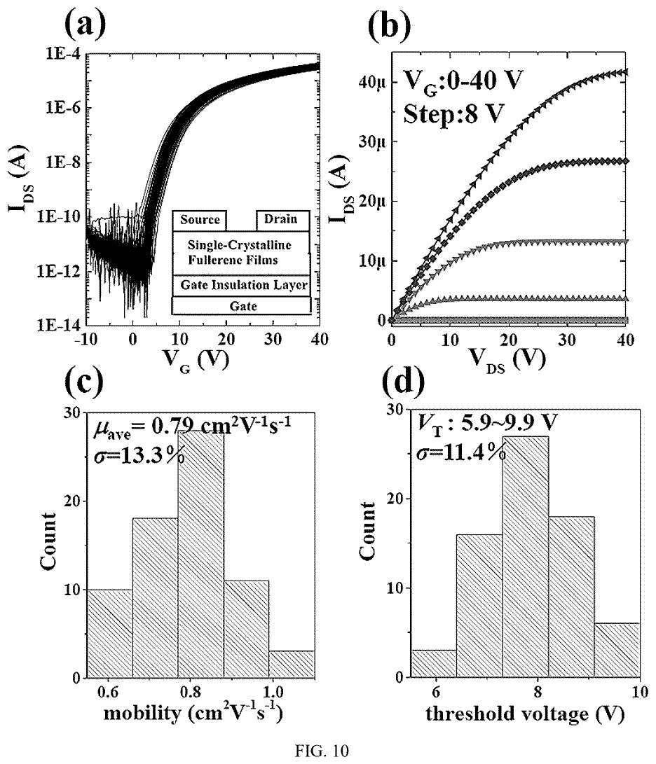

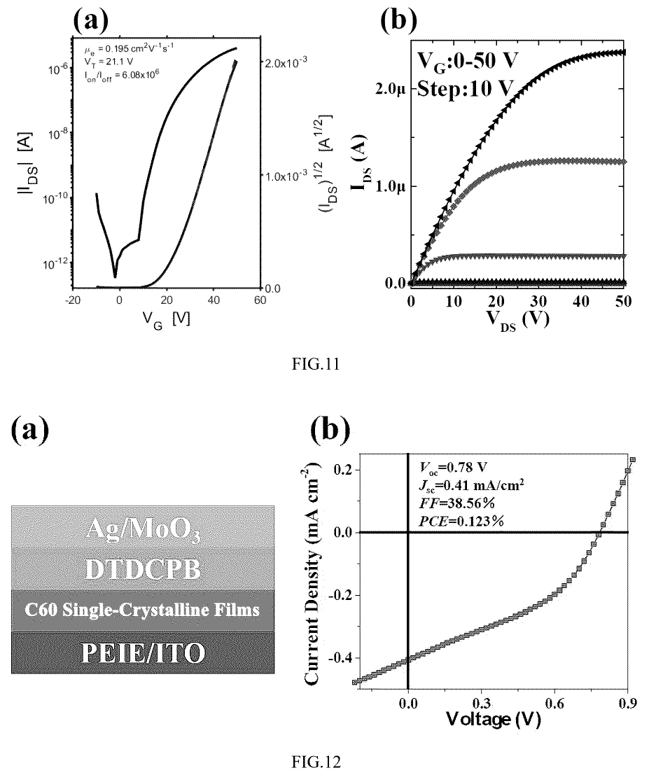

In a glove box, the N-type transfer characteristic curve (gate voltage V_{G}: −10 to 40 V; source-drain voltage V_{DS}: 40 V) and output characteristic curve (gate voltage V_{G}: 0 to 40 V, with an 8V step; source-drain voltage V_{DS}: 0 to 40 V) of these 70 OFETs were measured using a semiconductor parameter analyzer. The electron mobility (μ) and threshold voltage (VT) were extracted from the transfer characteristic curve, and the mean values and coefficient of variation (o, coefficient of variation=standard deviation/mean×100%) were calculated. The results are shown in FIG. 10.

The performance of OFETs largely depends on parameters such as mobility and threshold voltage. Among them, mobility is a decisive factor for OFET performance, as it reflects the carrier transport speed per unit electric field. Generally, higher mobility indicates better OFET performance. The threshold voltage is the minimum gate voltage required to turn on the transistor; the lower its absolute value, the better.

FIG. 10 shows that all 70 OFETs operated well, with good overlap in their transfer characteristic curves (FIG. 10a). The C60 fullerene single-crystal film of the present disclosure has excellent electron transport properties, with a maximum electron mobility exceeding 1 cm²V⁻¹s⁻¹, meeting the requirements for most organic circuits, sensor applications, or flexible displays. The coefficient of variation for electron mobility and threshold voltage is 13.3% (FIG. 10c) and 11.4% (FIG. 10d), respectively, indicating good uniformity for the fullerene single-crystal films produced. This coefficient of variation is significantly lower than the 42.9% reported by Jie et al. in 2021 for transistors based on single-crystal C60 arrays (Adv. Funct. Mater. 2021, 31, 2105459).

### Embodiment 11

In embodiment 11, an OFET was fabricated using the C70 fullerene single-crystal film from embodiment 8 with the following steps:

The basic procedure is the same as in embodiment 10, except that Ag was used as the source-drain electrode material.

In the glove box, the N-type transfer characteristic curve (V_{G}: −10 to 50 V; V_{DS}: 50 V) and output characteristic curve (V_{G}: 0 to 50 V, with a 10 V step; V_{DS}: 0 to 50 V) of the OFET were measured using a semiconductor parameter analyzer, with results shown in FIG. 11.

The on/off ratio (Iₒₙ/I_{off}) is an important performance indicator for OFETs, representing the current ratio in the ON and OFF states. A larger on/off ratio implies better performance.

FIG. 11 shows that the electron mobility of the OFET fabricated with the C70 fullerene single-crystal film reached 0.195 cm²V⁻¹s⁻¹, said mobility is the highest value currently reported for C70 fullerene-based OFETs. In comparison, the maximum electron mobility of single-crystal C70 fullerene in the existing literature is only 0.0132 cm²V⁻¹s⁻¹ (Chemical Physics Letters, 2022, 807, 140094).

### Embodiment 12

In embodiment 12, an organic solar cell was fabricated using the C60 fullerene single-crystal film from embodiment 7, with the following steps:
1) A 60 nm-thick layer of DTDCPB was deposited on the C60 fullerene single-crystal film prepared in embodiment 7 using vapor deposition to form a bilayer structure.
2) A 10 nm-thick layer of molybdenum trioxide and an 80 nm layer of silver were deposited on the bilayer structure as the top electrode, resulting in an organic solar cell.
3) The organic solar cell from Step 2) was illuminated using a solar simulator in a glove box, and a semiconductor parameter analyzer was used to obtain the current density-voltage (J-V) curve. Based on the J-V curve, the open-circuit voltage (Voc), short-circuit current (Jsc), fill factor (FF), and power conversion efficiency (PCE) were calculated, with results shown in FIG. 12.

Open-circuit voltage (Voc) refers to the voltage generated when the device is illuminated without an external circuit (positive and negative electrodes open), representing the maximum output voltage of the solar cell, measured in volts (V). Short-circuit current (Jsc) is the current generated when the illuminated device forms a closed loop (positive and negative electrodes short-circuited) with no external electric field applied, representing the maximum output current of the solar cell, measured in A/cm² or mA/cm². The fill factor (FF) is the ratio of the product of the current and voltage at the maximum output power of the cell to the product of the short-circuit current and open-circuit voltage. Power conversion efficiency (PCE) indicates the efficiency of the solar cell in converting solar energy into electrical energy.

FIG. 12 shows that the organic solar cell fabricated using the high-coverage fullerene single-crystal film in the present disclosure exhibits good photovoltaic effect, with a photoelectric conversion efficiency reaching 0.123%, demonstrating the potential of fullerene single-crystal films for applications in the photoelectric field.

### Embodiment 13

In embodiment 13, an organic complementary inverter was fabricated using the C60 fullerene single-crystal film from embodiment 1, with the following steps:
1) A single-crystal thin film of 1,4,8,11-tetramethyl-6,13-(triethylsilyl ethynyl) pentacene (TMTES-PEN) was grown on the another side of the C60 fullerene single-crystal film substrate from embodiment 1. The growth method used was the same solution-shearing technique as for the fullerene single-crystal film in embodiment 1, with a different concentration of the mixture formed by the solvent and TMTES-PEN, a different substrate temperature, and a different shearing speed of meta-xylene, which are 8 mg/mL, 40° C., and 50 μm/s, respectively.
2) An 80 nm-thick silver electrode was deposited on the substrate containing both fullerene single-crystal and TMTES-PEN single-crystal films.
3) In a glove box, a semiconductor analyzer was used to test the voltage transfer curve and voltage gain curve of the organic complementary inverter.

The voltage transfer curve shows the output voltage (Vₒᵤₜ) as a function of the input voltage (Vᵢₙ), while the voltage gain can be described by the formula d Vₒᵤₜ/d Vᵢₙ.

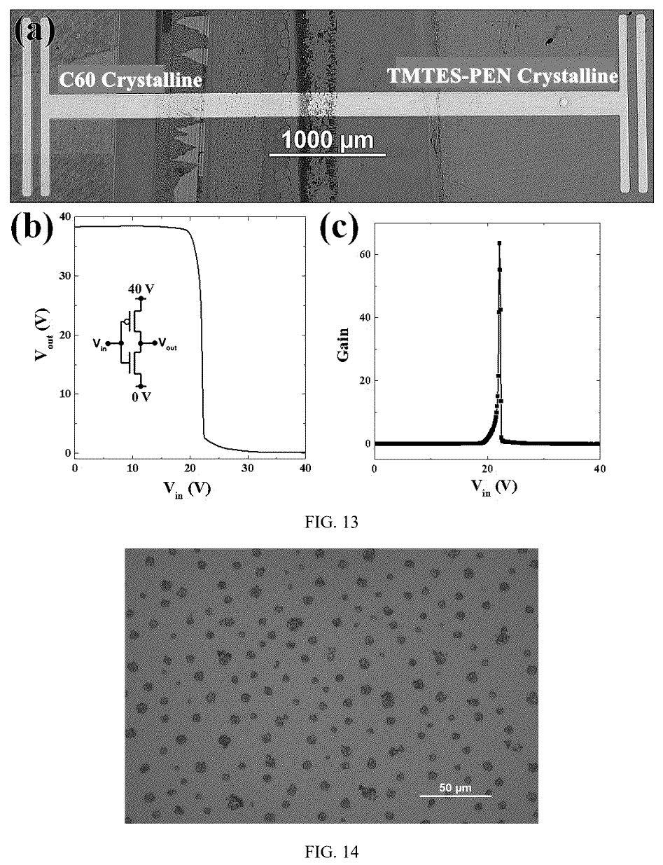

As shown in FIG. 13, the voltage inversion position in the voltage transfer curve (FIG. 13b) is close to half the ideal supply voltage (V_{DD}) at approximately 20 V, with minimal voltage loss. When the organic complementary inverter operates at V_{DD}=40V, the voltage gain reaches 63.5 (FIG. 13c). The good voltage inversion characteristic indicates that the fullerene single-crystal films in the present disclosure has potential for use in complementary integrated circuits.

### Comparative Example 1

The main difference between comparative example 1 and embodiment 1 is that, in comparative example 1 the growth temperature was reduced by 10° C., meaning the growth temperature was set to 25° C., when all other conditions were identical to those in embodiment 1. Specific materials and parameters are shown in Table 1.

The morphology of the film obtained in comparative example 1 was characterized using an optical microscope, and the results are shown in FIG. 14.

As observed from FIG. 14, a lower growth temperature led to slower solvent evaporation at the three-phase line, resulting in insufficient nucleation density of C60 fullerene, and consequently, no C60 fullerene crystal formed.

### Comparative Example 2

The main difference between comparative example 2 and embodiment 1 is that, in comparative example 2 the growth temperature was increased by 10° C., setting it to 45° C., with all other conditions identical to those in embodiment 1. Specific materials and parameters are presented in Table 1.

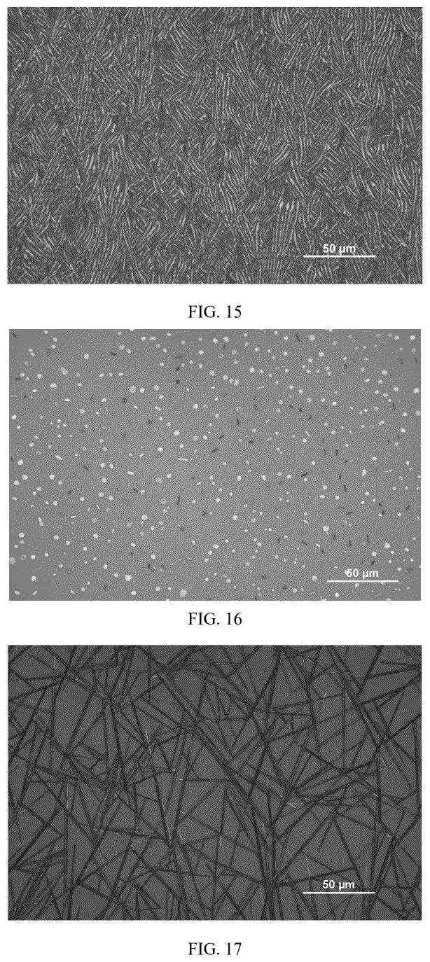

The morphology of the film obtained in comparative example 2 was characterized by optical microscopy, with results shown in FIG. 15.

As illustrated in FIG. 15, the higher growth temperature led to faster solvent evaporation, resulting in an excessively high nucleation density at the three-phase line. Although sufficient solute was available for crystallization growth, the final C60 fullerene crystal had disordered alignment and uneven morphology.

### Comparative Example 3

In comparative example 3, the main difference from embodiment 2 is the use of carbon tetrachloride as the sole solvent, while all other conditions remained the same as in embodiment 2. Specific materials and parameters are shown in Table 1.

The morphology of the thin film obtained in comparative example 3 was characterized using an optical microscope, with results presented in FIG. 16.

As shown in FIG. 16, when only carbon tetrachloride was used as the solvent, only small and discontinuous hexagonal crystals could be obtained, consistent with findings in the literature (Chem. Commun. 2009, 4803-4805). However, using a mixed solvent of carbon tetrachloride and 3-methylthiophene combined the properties of hexagonal and one-dimensional crystal, yielding ribbon-shaped crystal with both high coverage and good alignment (FIG. 2), increasing the coverage by more than 8 times. This result indicates that solvent selection significantly improves fullerene crystal morphology during preparation, promoting its practical application across various fields.

### Comparative Example 4

In comparative example 4, the main difference from embodiment 3 is the use of meta-xylene as the sole solvent, with all other conditions identical to those in embodiment 3. Specific materials and parameters are listed in Table 1.

The morphology of the thin film obtained in comparative example 4 was characterized by optical microscopy, and the results are shown in FIG. 17.

As observed in FIG. 17, using only meta-xylene as the solvent resulted in low coverage, misaligned, and stacked one-dimensional needle-like crystal. In contrast, using a mixed solvent of meta-xylene and 2-chlorothiophene produced high-coverage, uniformly aligned ribbon-shaped crystal (FIG. 3), with coverage increasing by approximately 5.3 times. These findings highlight the importance of solvent selection in the preparation of fullerene single-crystal films.

The above examples are intended to illustrate the embodiments disclosed in the present disclosure and should not be construed as limiting the present disclosure. Furthermore, various modifications and variations to the methods and compositions within the scope and spirit of this invention will be apparent to those skilled in the field. Although the present disclosure has been specifically described with various preferred embodiments, it should be understood that the present disclosure is not limited to these specific embodiments. In fact, various modifications to obtain the present disclosure as described above, which are apparent to those skilled in the art, should be included within the scope of the present disclosure.

1. A method for preparing fullerene single-crystal films using a gas-liquid-solid three-phase interface, comprising:
1) mixing fullerene and solvent to form a mixture; and
2) employing a solution shear method to induce crystallization growth of the fullerene in mixture on a substrate surface, thereby obtaining the fullerene single-crystal films.

2. The method according to claim 1, further comprising at least one of following technical features:
A1) the fullerene is one or more of C60, C70, C76, C78, C80, and C84;
A2) the solvent is one or more of ortho-xylene, 2-methylthiophene, 2-chlorothiophene, 2-chloro-furan, 3-methylthiophene, 2-ethylthiophene, meta-xylene, meta-difluorobenzene, chlorobenzene, ortho-dichlorobenzene, 1,2,4-trichlorobenzene, tetrahydronaphthalene, 1-methylnaphthalene, carbon disulfide, 1,1,2,2-tetrachloroethane, carbon tetrachloride, 2-methoxythiophene, phenethyl ether, 2-chloro-3-methylthiophene, and 2,5-dichlorothiophene;
A3) a concentration of the fullerene, based on a total volume of the mixture, is 0.2 mg/mL to 20 mg/mL, preferably 0.4 mg/ml to 10 mg/mL;
A4) a material of the substrate is one or more of silicon, indium tin oxide, glass, quartz, sapphire, polyimide, and polyethylene terephthalate; and
A5) a temperature for the crystallization growth is 20° C. to 120° C., preferably 25° C. to 60° C.

3. The method according to claim 2, wherein a wetting layer is provided on the substrate.

4. The method according to claim 3, wherein a material of the wetting layer is one or more of benzocyclobutene, polyvinyl alcohol, cross-linked polymethyl methacrylate, cross-linked polystyrene, aluminum oxide, titanium oxide, zinc oxide, ethoxylated polyethyleneimine, phenyltrichlorosilane, gold, and aluminum.

5. The method according to claim 1, wherein step 2), the solution shear method comprises using a shear tool positioned above the substrate, such that the mixture is located between the shear tool and the substrate, and either the substrate or the shear tool is operated at a certain linear velocity.

6. The method according to claim 5, wherein the shear tool is one or more of stainless-steel bar, stainless steel wire bar, polytetrafluoroethylene bar, scrapers, and coating heads;
wherein a distance between the shear tool and the substrate is 20 μm to 400 μm, preferably 50 μm to 200 μm; and
wherein the certain linear velocity in the solution shear method is 1 μm/s to 1 mm/s, preferably 5 μm/s to 200 μm/s.

7. Fullerene single-crystal films obtained by the method for preparing fullerene single-crystal films using a gas-liquid-solid three-phase interface according to claim 1.

8. Use of the fullerene single-crystal films according to claim 7 in an optoelectronic device.

9. An optoelectronic device, wherein the optoelectronic device comprises the fullerene single-crystal films according to claim 7.

10. The optoelectronic device according to claim 9, wherein the optoelectronic device is one or more of organic field-effect transistors, organic solar cells, organic complementary inverters, organic circuits, organic light-emitting diodes, organic memory devices, organic photodetectors, and organic thermoelectric devices.
